(19) United States
(12) Patent Application Publication
(10) Pub. No.: US 2015/0295193 A1
(43) Pub. Date: Oct. 15, 2015

(54) SEMICONDUCTOR DEVICE USING PAPER AS A SUBSTRATE AND METHOD OF MANUFACTURING THE SAME

(71) Applicant: UNIVERSITY OF SEOUL INDUSTRY COOPERATION FOUNDATION, Dongdaemum-gu, Seoul (KR)

(72) Inventor: Byung Eun Park, Seoul (KR)

(73) Assignee: University of Seoul Industry Cooperation Foundatio n, Seoul (KR)

(21) Appl. No.: 14/646,885

(22) PCT Filed: Nov. 22, 2013
(86) PCT No.: PCT/KR2013/010702

§ 371 Date: May 22, 2015

(30) Foreign Application Priority Data
Nov. 22, 2012 (KR) 10-2012-0133224
Nov. 22, 2012 (KR) 10-2012-0133257
Nov. 22, 2013 (KR) 10-2013-0142563
Nov. 22, 2013 (KR) 10-2013-0142564

(51) Int. Cl. H01L 51/00; H01L 51/10; H01L 51/05

(52) U.S. Cl. CPC H01L 51/0097; H01L 51/052; H01L 51/0525; H01L 51/0545; H01L 51/055; H01L 51/0558; H01L 51/0021; H01L 51/0537; H01L 51/105; H01L 51/0036; H01L 51/0034

(57) ABSTRACT

Disclosed are a semiconductor device manufactured using a paper as a substrate and a method of manufacturing the same. According to an embodiment of the present invention, the semiconductor device is manufactured by using a paper including pulp as a raw material or paper as a substrate coated with a heat-resistant material such as silicon. According to the present invention, a metal wiring layer such as a gate electrode is formed on the paper substrate by using a vacuum deposition method, or the like and an insulating layer is stacked thereon.

### TECHNICAL FIELD

The present invention relates to a semiconductor device such as a transistor or a memory device, and more particularly, to a semiconductor device manufactured by using a paper as a substrate and a method of manufacturing the same.

### BACKGROUND ART

A semiconductor device such as a transistor or a memory may be manufactured by a method of forming a plurality of wiring layers or an inorganic material layer on, for example, a silicon substrate, or the like. However, in order to manufacture a silicon substrate, a complicated process of forming an ingot by growing silicon to have constant directivity and then cutting and mirror-like finishing the ingot is required.

Meanwhile, Korean Patent Application Nos. 10-2007-0030811 and 10-2009-0014155 disclose a method of manufacturing an electronic device by a method of forming various wiring layers on a paper, coated paper, or plastic using an electrophotography technology.

However, since the above-mentioned method charges a drum, attaches a toner to the drum, and carries out printing, it is difficult to form a nano wiring, and since the toner previously attached to the drum is not completely removed at the time of forming another wiring layer and therefore acts as a pollutant, it is inappropriate for use in the manufacture of high precision devices such as a semiconductor device.

### DISCLOSURE OF INVENTION

### Technical Problem

Accordingly, in consideration of the above-mentioned circumstances, it is an object of the present invention to provide a method of manufacturing a semiconductor device on a paper substrate.

Another object of the present invention is to provide a semiconductor device manufactured by the above method of manufacturing a semiconductor device.

### Solution to Problem

To accomplish the above objects, a method of manufacturing a semiconductor device using a paper as a substrate according to a first aspect of the present invention, includes: preparing a paper substrate; forming a gate electrode having a thickness of 150 nm or more on the paper substrate; forming an insulating layer on the gate electrode; forming a channel forming layer formed on the insulating layer; and forming source and drain electrodes on the channel forming layer.

A method of manufacturing a semiconductor device using a paper as a substrate according to a second aspect of the present invention, includes: preparing a paper substrate; increasing flatness of the paper; forming a channel forming layer on the paper substrate; forming source and drain electrodes on the channel forming layer; forming an insulating layer between the source and drain electrodes on the channel forming layer; and forming a gate electrode on the insulating layer.

Preferably, the preparing of the paper substrate further includes removing moisture or air contained in a paper tissue.

Preferably, the channel forming layer is formed as an organic semiconductor or an insulating layer.

Preferably, the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

A semiconductor device using a paper as a substrate according to a third aspect of the present invention, includes: a paper substrate; a gate electrode formed on the paper substrate and having a thickness of 150 nm or more; an insulating layer formed on the gate electrode; a channel forming layer formed on the insulating layer; and source and drain electrodes formed on the channel forming layer.

A semiconductor device using a paper as a substrate according to a fourth aspect of the present invention, includes: a paper substrate; source and drain electrodes formed on the paper substrate and having a thickness of 150 nm or more; a channel forming layer formed over all the paper substrate and the source and drain electrodes; an insulating layer formed on the channel forming layer; and a gate electrode formed on the insulating layer.

Preferably, the source and drain electrodes include metal.

Preferably, the channel forming layer is formed as an organic semiconductor or an insulating layer.

Preferably, the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

Preferably, the source and drain electrodes are made of a conductive organic material.

Preferably, the paper substrate is a paper coated with a heat-resistant material.

A semiconductor device using a paper as a substrate according to a fifth aspect of the present invention, includes: a paper substrate; a gate electrode formed on the paper substrate and having a thickness of 150 nm or more; an insulating layer formed on the gate electrode; source and drain electrodes each formed on both sides of the gate electrode; and a channel forming layer formed on the insulating layer and the source and drain electrodes.

A semiconductor device using a paper as a substrate according to a sixth aspect of the present invention, includes: a paper substrate; a gate electrode formed on the paper substrate and made of aluminum (Al); an insulating layer formed on the gate electrode and made of P (VDF-TrFE); a channel forming layer formed on the insulating layer and made of P3HT; and source and drain electrodes formed on the channel forming layer.

### Advantageous Effects of Invention

According to the present invention having the above mentioned configuration, the semiconductor devices, such as a transistor or a memory device, may be formed on the paper substrate, and not on a conventional silicon substrate. Therefore, the manufacturing cost of the semiconductor device may be very low and the metal, etc., formed on the paper substrate may be easily recovered.

### BRIEF DESCRIPTION OF DRAWINGS

FIG. 1 is a cross-sectional view illustrating a structure of a semiconductor device according to an embodiment of the present invention.

FIG. 2 is a diagram illustrating a sectional structure of the semiconductor device illustrated in FIG. 1 formed on a commercial paper, which is photographed by an electron microscope.

FIG. 3 is an enlarged view of FIG. 2C.

FIG. 4 is a diagram illustrating the sectional structure of the semiconductor device on a silicon wafer, which is photographed by the electron microscope.

FIG. 5 is a characteristic graph shown by comparing polarization values depending on electric field values at a frequency of 100 Hz between the semiconductor device according to the present invention and a conventional semiconductor device formed on the silicon substrate.

FIG. 6 is a characteristic graph illustrating coercive electric field values and polarization values depending on each frequency between the semiconductor device according to the present invention and the conventional semiconductor device formed on the silicon substrate.

FIG. 7 is a characteristic graph shown by comparing drain current values depending on gate voltages between the semiconductor device according to the present invention and the conventional semiconductor device formed on the silicon substrate.

FIG. 8 is a cross-sectional view of a structure example of a semiconductor device according to another embodiment of the present invention.

### BEST MODE FOR CARRYING OUT THE INVENTION

Hereinafter, preferable embodiments of the present invention will be described with reference to the accompanying drawings. However, those skilled in the art will appreciate that such embodiments are provided for illustrative purposes and do not limit subject matters to be protected as disclosed in the detailed description and appended claims. Therefore, it will be apparent to those skilled in the art that various alterations and modifications of the embodiments are possible within the scope and spirit of the present invention and duly included within the range as defined by the appended claims.

In this disclosure, the paper includes all kinds of paper manufactured from pulp as a main material and papers coated with a heat-resistant material such as silicon.

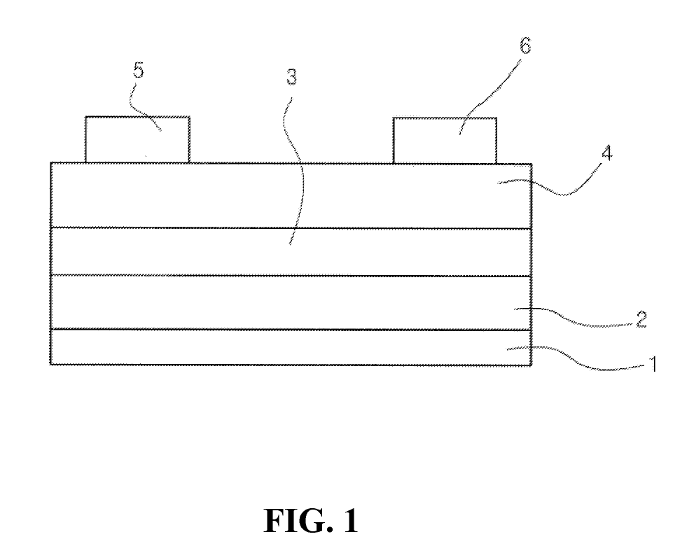

FIG. 1 is a cross-sectional view illustrating a structure of the semiconductor device according to an embodiment of the present invention, which illustrates a sectional structure of a memory device having, in particular, a 1-transistor structure.

In FIG. 1, reference numeral 1 is a paper substrate. A metal wiring 2 which is made of a conductive metal, such as gold (Au), platinum (Pt), silver (Ag), and aluminum (Al) is formed on the paper substrate 1. The metal wiring 2 is provided as a gate electrode, which is formed on the paper substrate 1 by a vacuum deposition method.

Next, a ferroelectric film or a ferroelectric layer 3 which is made of a ferroelectric material is formed on the metal wiring 2. In this case, as the ferroelectric material forming the ferroelectric layer 3, an inorganic material such as PZT, an organic material such as PVDF, a mixture of an inorganic ferroelectric material with an organic material or an organic ferroelectric material, a mixture of the inorganic ferroelectric material with metal, preferably, iron (Fe), or the like are used.

Further, in the case of the inorganic ferroelectric material, the vapor deposition method is used to form the ferroelectric layer 3 and in the case of the mixture of the organic ferroelectric material or the inorganic ferroelectric material with the organic material or the organic ferroelectric material, a spin coating method, or the like is used to form the ferroelectric layer 3.

Next, a channel forming layer 4 is formed on the ferroelectric layer 3. The channel forming layer 4 is formed by vacuum-depositing or spin-coating an organic semiconductor such as pentacene.

Further, in addition to the pentacene, an example of the organic semiconductor may include Cu-phthalocyanine, polyacetylene, merocyanine, polythiophene, phthalocyanine, poly (3-hexylthiophene), poly (3-alkylthiophene), α-sexithiophene, α-ω-dihexyl-sexithiophene, polythienylenevinylene, bis (dithienothiophene), α-ω-dihexyl-quaterthiophene, dihexyl-anthradithiophene, α-ω-dihexyl-quinquethiophene, F8T2, Pc₂Lu, Pc₂Tm, C₆₀/C₇₀, TCNQ, C₆₀, PTCDI-Ph, TCNNQ, NTCDI, NTCDA, PTCDA, F16CuPc, NTCDI-C8F, DHF-6T, PTCDI-C8, or the like may be used.

Further, as the channel forming layer 4, an insulating layer may be used. In this case, as the insulating layer, an inorganic material such as ZrO₂, SiO₄, Y₂O₃, and CeO₂ or an organic material such as BCB, polyimide, acryl, parylene C, PMMA, and CYPE may be used.

Further, the memory device is completed by forming a source electrode 5 and a drain electrode 6 on the channel forming layer 4.

In this case, the source electrode 5 and the drain electrode 6 are made of the following materials: gold, silver, aluminum, platinum, indium tin oxide (ITO) compound, and strontium titanate (SrTiO₃) compound, other conductive metal oxides and an alloy and a compound thereof, or a mixture, a compound, or a multi-layered material of, for example, polyaniline, poly (3,4-ethylenedioxythiophene):polystyrenesulfonate (PEDOT:PSS), etc., using a conductive polymer as a base.

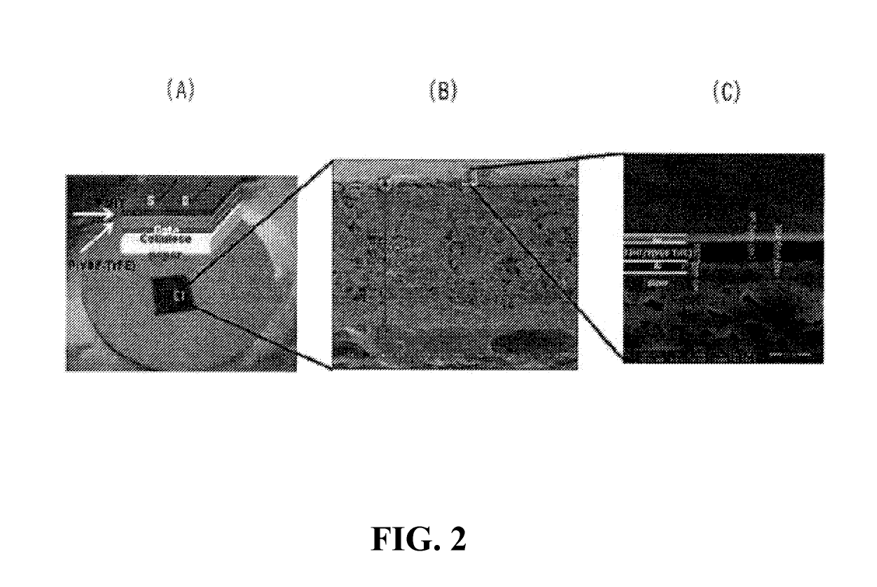

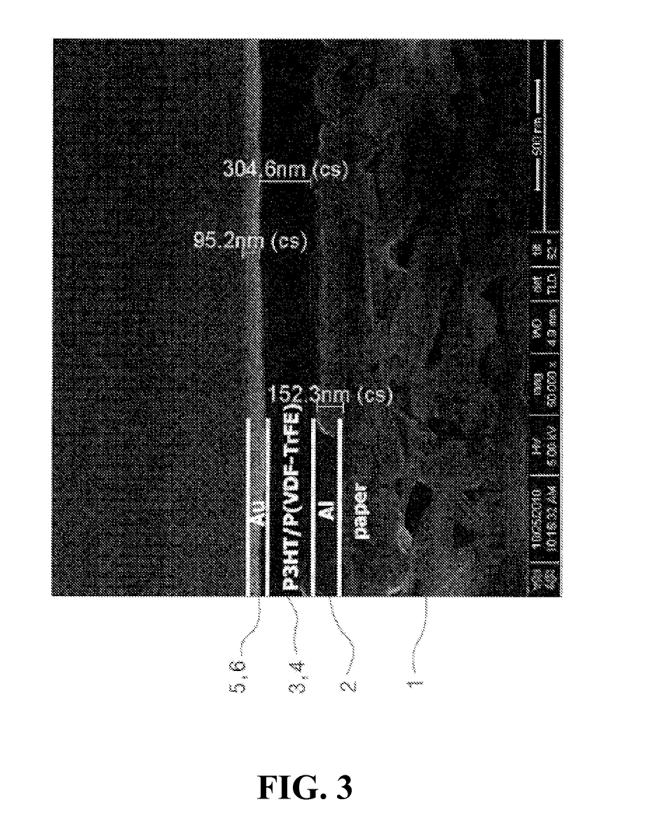

FIG. 2 is a diagram illustrating the sectional structure of the semiconductor device illustrated in FIG. 1 formed on a commercial paper, which is photographed by an electron microscope. Further, FIG. 3 is an enlarged view of FIG. 2C.

In FIGS. 2 and 3, a gate electrode 2 made of aluminum (Al) is formed on the paper substrate 1. In the present Example, a thickness of the formed gate electrode 2 was 152.3 nm. The gate electrode 2 was formed by the vacuum deposition method. According to the study of the present inventors, since the paper substrate 1 has low flatness, the thickness of the gate electrode 2 has a large effect on the flatness of the gate electrode 2. That is, when the thickness of the gate electrode is reduced, the flatness of the gate electrode deteriorates. Further, the deterioration in the flatness acts as a cause of increasing a leakage current. Therefore, the gate electrode 2 may have a thickness of preferably 150 nm or more, and more preferably 200 nm or more. Further, when the thickness of the gate electrode 2 is increased, the paper substrate 1 is exposed to heat for a longer period of time, such that a fiber of paper may be damaged. Therefore, in the case of increasing the thickness of the gate electrode 2, a method of depositing the gate electrode 2 under an inert gas atmosphere may be preferably adopted.

A P (VDF-TrFE) layer as the ferroelectric layer 3 was formed on the gate electrode 2. The P (VDF-TrFE) layer was formed by dissolving 70:30 mol % of P (VDF-TrFE) into 4 wt % of 2-butanol solvent and then spin-coating it at a rate of 3000 rpm for 25 seconds.

The channel forming layer 4 was formed by forming the P (VDF-TrFE) layer and then carrying out annealing thereon at 140° C. for about 1 hour to evaporate the solvent. In the present Example, P3HT was used to form the channel forming layer 4. That is, the channel forming layer 4 was formed by dissolving the P3HT into 0.7 wt % of solvent and carrying out the spin coating thereon at a rate of 2500 rpm for 25 seconds and the annealing thereof at 140° C. for 1 hour.

Further, the source electrode 5 and the drain electrode 6 were formed by vacuum-depositing Au on the channel forming layer 4.

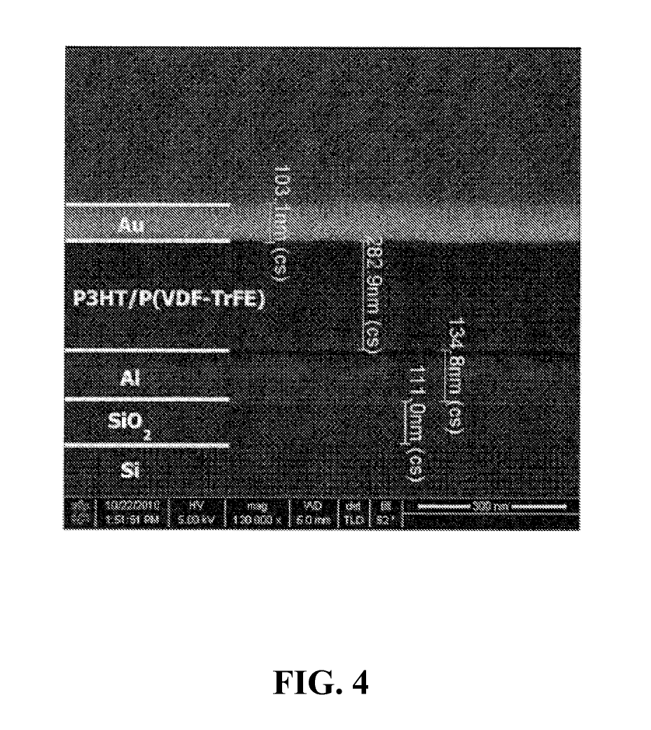

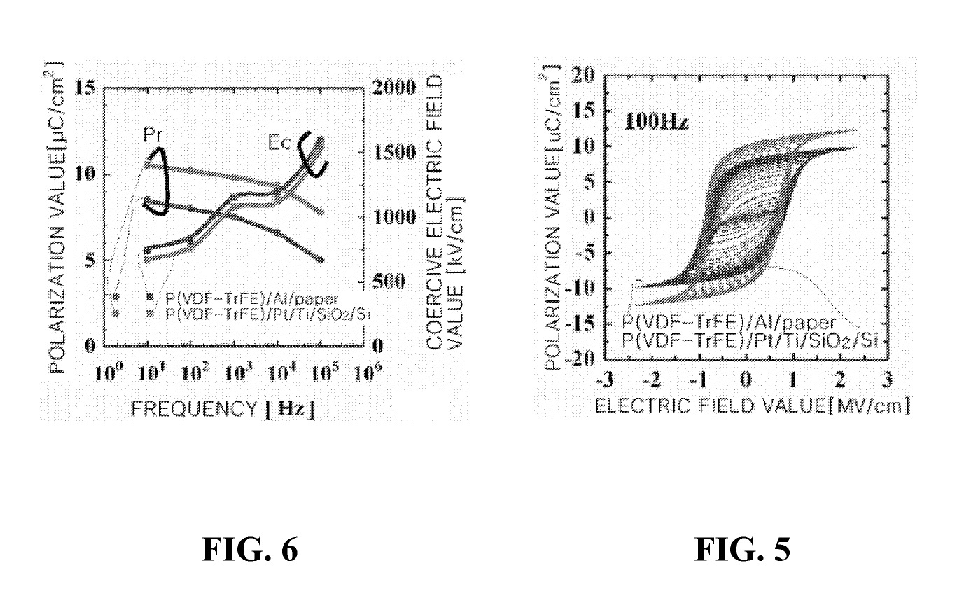

Meanwhile, for comparing characteristics of the semiconductor device according to the present invention, a semiconductor device was implemented on a conventional silicon wafer. FIG. 4 is a diagram illustrating the sectional structure of the semiconductor device having the structure illustrated in FIG. 1 on the silicon wafer, which is photographed by the electron microscope. According to Comparative Example of FIG. 5, a P3HT/P (VDF-TrFE) layer having a thickness of 282.9 nm is formed on the silicon wafer coated with SiO₂ by a conventional method.

FIG. 5 is a characteristic graph obtained by comparing polarization values depending on electric field values at a frequency of 100 Hz between the semiconductor device according to the present invention and the conventional semiconductor device formed on the silicon substrate and FIG. 6 is a characteristic graph illustrating coercive electric field values and polarization values depending on each frequency.

As can be appreciated from the FIGS. 5 and 6, the semiconductor device according to the present invention shows good hysteresis characteristics similar to the conventional semiconductor device. Further, it was confirmed that the semiconductor device according to the present invention and the conventional semiconductor device show a slight difference in a residual polarization value Pr and have substantially the same coercive electric field value. That is, the semiconductor device according to the present invention which is the same as one of the related art may be adopted.

The semiconductor device illustrated in FIG. 1 is a memory device having a 1-transistor structure. In the memory device according to the present invention, the ferroelectric layer 3 has a polarization value depending on the voltage applied to the gate electrode 2 and the channel is selectively formed on the channel forming layer 4 depending on the polarization value of the ferroelectric layer 3, such that a current between the source electrode 5 and the drain electrode 6 may be set to be a conducting or non-conducting state.

Further, in the above 1T structure, data “0” and “1” are recognized depending on a turn on/off state of the transistor.

The above structure is implemented on the paper substrate, not on the conventional silicon substrate. Therefore, the manufacturing cost of the memory device is remarkably reduced and in the case of discarding the present device later, the metal formed on the paper substrate may be easily recovered by a simple operation of removing paper.

Further, the semiconductor device illustrated in FIG. 1 may be adopted as one transistor in addition to the memory device.

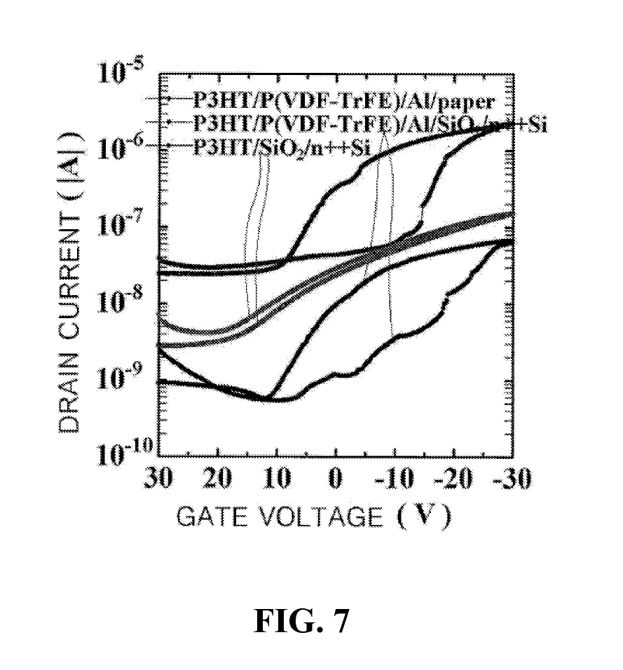

FIG. 7 is a characteristic graph shown by comparing drain current values depending on gate voltages between the semiconductor device according to the present invention and the conventional semiconductor device formed on the silicon substrate, that is, a first Comparative Example in which the insulating layer of SiO₂ is formed on the silicon substrate and a second Comparative Example in which the insulating layer of a ferroelectric material is formed on the silicon substrate.

Similar to the conventional semiconductor device, it can be appreciated from FIG. 7 that the semiconductor device according to the present invention shows a good on/off ratio depending on the gate voltage. However, comparing to the conventional semiconductor device, the semiconductor device according to the present invention shows a high drain current value. This means that a leakage current value is high. It is understood that the high leakage current value is due to the flatness of the paper substrate 1. Therefore, when the gate electrode 2 is formed on the paper substrate 1, a method of improving the flatness of the paper substrate 1 by using a method of thermally compressing the paper substrate 1 to improve the flatness of the gate electrode 2, or the like may be preferably adopted.

Meanwhile, the foregoing embodiment describes, by way of example, an inverted staggered structure in which the gate electrode 2 is formed on the paper substrate 1 using the metal wiring and the ferroelectric layer 3 and the channel forming layer 4 are sequentially formed thereon, but the present invention is not limited thereto, and may be applied to a staggered structure, a coplanar structure, and an inverted coplanar structure in addition to the above structure in the same manner.

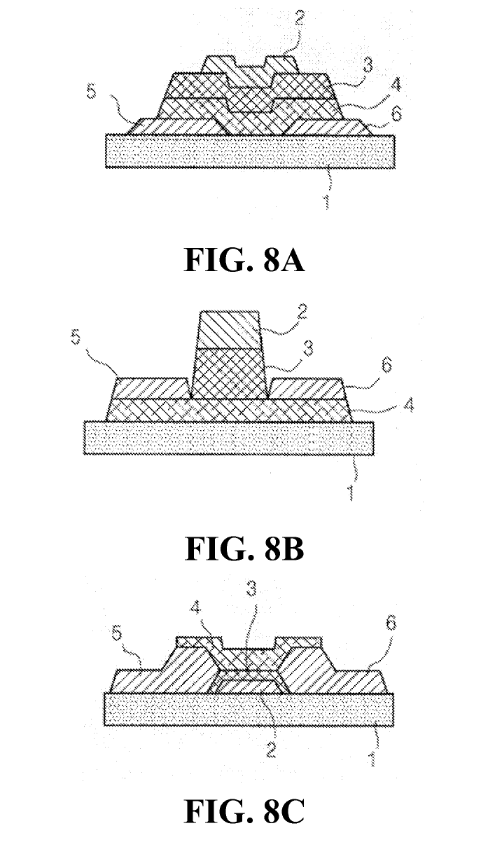

FIG. 8 is a cross-sectional view of another structure example of a transistor or a memory device to which the present invention may be applied, in which FIG. 8A illustrated the staggered structure, FIG. 8 illustrates the coplanar structure, and FIG. 8C illustrated the inverted coplanar structure. Further, in FIG. 8, components corresponding to ones of FIG. 1 are denoted by the same reference numerals.

In the staggered structure illustrated in FIG. 8A, the source electrode 5 and the drain electrode 6 are formed on the paper substrate 1 by the vacuum deposition and the channel forming layer 4 is entirely formed on the structure in which these electrodes 5 and 6 are formed, by using, for example, the vacuum deposition or the spin coating. In this case, the source electrode 5 and the drain electrode 6 are preferably formed at 150 nm or more, more preferably, 200 nm or more in consideration of the flatness of the paper substrate 1.

Even in this case, as the channel forming layer 4, the organic semiconductor layer or the insulating layer may be used.

Further, the ferroelectric layer 3 and the gate electrode 2 are sequentially formed on the channel forming layer 4 to configure the transistor or the memory device.

In the coplanar structure illustrated in FIG. 8B, the channel forming layer 4 of the organic material or the insulating layer is entirely formed on the paper substrate 1 by the vacuum deposition or the spin coating and the source and drain electrodes 5 and 6 are formed thereon.

Further, the ferroelectric layer 3 is formed between the source and drain electrodes 5 and 6 on the channel forming layer 4 and then the gate electrode 2 is formed on the ferroelectric layer 3 to configure the transistor or the memory device.

In the inverted coplanar structure illustrated in FIG. 8C, the gate electrode 2 such as the metal wiring is formed on the paper substrate 1 by the vacuum deposition method and the ferroelectric layer 3 is formed on the gate electrode 2. Further, the channel forming layer 4 of the organic material or the insulating layer is formed on the ferroelectric layer 3, and the source and drain electrodes 5 and 6 are formed on both sides thereof to configure the transistor.

The embodiments of the present invention are described above. However, the present invention are not limited to the above embodiments, but may be variously modified without departing from the technical idea of the present invention.

For example, the embodiments of the present invention as described above illustrate that the gate electrode is formed by using the metal wiring, but the conductive organic material, or the like may be formed by a printing method, such as inkjet and screen printing, or the like.

Further, according to the above embodiments of the present invention, in the case of forming the gate electrode 2 on the paper substrate 1, the method of improving the flatness of the paper substrate 1 by using the method of thermally compressing the paper substrate 1 to improve the flatness of the gate electrode 2, or the like may be preferably adopted.

Further, according to the embodiments of the present invention, in the case of preparing the paper substrate 1, a method of removing moisture contained in the paper by heating the paper substrate 1 under the inert gas atmosphere may be preferably adopted.

Although the present invention has been described in connection with the embodiments illustrated in the drawings, it is only illustrative. It will be understood by those skilled in the art that various modifications and equivalents can be made to the present invention. Therefore, the true technical scope of the present invention should be defined by the appended claims.

### DESCRIPTION OF REFERENCE NUMERALS

1: paper substrate 2: gate electrode
3: insulating layer 4: channel forming layer
5: source electrode 6: drain electrode

### INDUSTRIAL APPLICABILITY

According to the present invention having the above mentioned configuration, the semiconductor devices, such as a transistor or a memory device, may be formed on the paper substrate, and not on a conventional silicon substrate. Therefore, the manufacturing cost of the semiconductor device may be very low and the metal, etc., formed on the paper substrate may be easily recovered.

1. A method of manufacturing a semiconductor device using a paper as a substrate, comprising: preparing a paper substrate; forming a gate electrode having a thickness of 150 nm or more on the paper substrate;
forming an insulating layer on the gate electrode; forming a channel forming layer formed on the insulating layer; and forming source and drain electrodes on the channel forming layer.

2. The method of claim 1, wherein the preparing of the paper substrate further comprises increasing flatness of the paper.

3. The method of claim 1, wherein the forming of the gate electrode is carried out by a method of vacuum-depositing a conductive metal.

4. The method of claim 1, wherein the channel forming layer is formed as an organic semiconductor or an insulating layer.

5. The method of claim 1, wherein the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

6. A method of manufacturing a semiconductor device using a paper as a substrate, comprising: preparing a paper substrate; forming source and drain electrodes having a thickness of 150 nm or more on the paper substrate; forming a channel forming layer on the paper substrate and the source and drain electrodes; forming an insulating layer on the channel forming layer; and forming a gate electrode on the insulating layer.

7. The method of claim 6, wherein the preparing of the paper substrate further comprises increasing flatness of the paper.

8. The method of claim 6, wherein the forming of the gate electrode is carried out by a method of vacuum-depositing a conductive metal.

9. The method of claim 6, wherein the channel forming layer is formed as an organic semiconductor or an insulating layer.

10. The method of claim 6, wherein the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

11. A method of manufacturing a semiconductor device using a paper as a substrate, comprising: preparing a paper substrate; increasing flatness of the paper; forming a channel forming layer on the paper substrate; forming source and drain electrodes on the channel forming layer; forming an insulating layer between the source and drain electrodes on the channel forming layer; and forming a gate electrode on the insulating layer.

12. The method of claim 11, wherein the preparing of the paper substrate further comprises removing moisture or air contained in a paper tissue.

13. The method of claim 11, wherein the channel forming layer is formed as an organic semiconductor or an insulating layer.

14. The method of claim 11, wherein the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

15. A semiconductor device using a paper as a substrate, comprising: a paper substrate; a gate electrode formed on the paper substrate and having a thickness of 150 nm or more; an insulating layer formed on the gate electrode; a channel forming layer formed on the insulating layer; and source and drain electrodes formed on the channel forming layer.

16. The semiconductor device of claim 15, wherein the gate electrode includes metal.

17. The semiconductor device of claim 15, wherein the channel forming layer is formed as an organic semiconductor or an insulating layer.

18. The semiconductor device of claim 15, wherein the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

19. The semiconductor device of claim 15, wherein the gate electrode is made of a conductive organic material.

20. The semiconductor device of claim 15, wherein the paper substrate is a paper coated with a heat-resistant material.

21. A semiconductor device using a paper as a substrate, comprising: a paper substrate; source and drain electrodes formed on the paper substrate and having a thickness of 150 nm or more; a channel forming layer formed over all the paper substrate and the source and drain electrodes; an insulating layer formed on the channel forming layer; and a gate electrode formed on the insulating layer.

22. The semiconductor device of claim 21, wherein the source and drain electrodes include metal.

23. The semiconductor device of claim 21, wherein the channel forming layer is formed as an organic semiconductor or an insulating layer.

24. The semiconductor device of claim 21, wherein the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

25. The semiconductor device of claim 21, wherein the source and drain electrodes are made of a conductive organic material.

26. The semiconductor device of claim 21, wherein the paper substrate is a paper coated with a heat-resistant material.

27. A semiconductor device using a paper as a substrate, comprising: a paper substrate; a gate electrode formed on the paper substrate and having a thickness of 150 nm or more; an insulating layer formed on the gate electrode; source and drain electrodes each formed on both sides of the gate electrode; and
a channel forming layer formed on the insulating layer and the source and drain electrodes.

28. The semiconductor device of claim 27, wherein the gate electrode and the source and drain electrodes include metal.

29. The semiconductor device of claim 27, wherein the channel forming layer is formed as an organic semiconductor or an insulating layer.

30. The semiconductor device of claim 27, wherein the insulating layer includes at least one of an inorganic ferroelectric material, an organic ferroelectric material, a mixture of the inorganic ferroelectric material with an organic material, a mixture of the inorganic ferroelectric material with the organic ferroelectric material, and a mixture of the inorganic ferroelectric material with metal.

31. The semiconductor device of claim 27, wherein the gate electrode and the source and drain electrodes are made of a conductive organic material.

32. The semiconductor device of claim 27, wherein the paper substrate is a paper coated with a heat-resistant material.

33. A semiconductor device using a paper as a substrate, comprising: a paper substrate; a gate electrode formed on the paper substrate and made of aluminum (Al); an insulating layer formed on the gate electrode and made of P (VDF-TrFE); a channel forming layer formed on the insulating layer and made of P3HT; and source and drain electrodes formed on the channel forming layer.
